(19) United States
(12) Patent Application Publication
(10) Pub. No.: US 2023/0076961 A1
(43) Pub. Date: Mar. 9, 2023

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventors: Aoi SUZUKI, Yokkaichi Mie (JP); Yoshiharu ONO, Yokkaichi Mie (JP); Ai MORI, Yokkaichi Mie (JP)

(73) Assignee: Kioxia Corporation, Tokyo (JP)

(21) Appl. No.: 17/672,750

(22) Filed: Feb. 16, 2022

(30) Foreign Application Priority Data
Sep. 6, 2021 (JP) 2021-144980

(51) Int. Cl. B23K 26/36; B23K 26/10; B23K 26/70

(52) U.S. Cl. CPC B23K 26/36; B23K 26/10; B23K 26/703; B23K 2101/40

(57) ABSTRACT

In one embodiment, a semiconductor manufacturing apparatus includes a reformed layer former configured to partially reform a first substrate to form a reformed layer between first and second portions in the first substrate, a peeling layer former configured to form a peeling layer between the second portion and a second substrate provided on the first substrate, and a remover configured to remove the second portion from the second substrate while causing the first portion to remain on the second substrate. The remover includes a heater to heat the first or second portion, to peel the second portion from the second substrate at the peeling layer and divide the first and second portions from each other, and a mover to move the second substrate relative to the second portion, to remove the second portion from the second substrate while causing the first portion to remain on the second substrate.

### CROSS REFERENCE TO RELATED APPLICATION

This application is based upon and claims the benefit of priority from the prior Japanese Patent Application No. 2021-144980, filed on Sep. 6, 2021, the entire contents of which are incorporated herein by reference.

### FIELD

Embodiments described herein relate to a semiconductor manufacturing apparatus and a method of manufacturing a semiconductor device.

### BACKGROUND

For example, when a semiconductor device is manufactured by bonding substrates, those substrates are often processed by trimming or grinding. In this case, it is desired to process those substrates by a suitable method.

### BRIEF DESCRIPTION OF THE DRAWINGS

FIG. 1 is a plan view illustrating a structure of a semiconductor manufacturing apparatus of a first embodiment;

FIGS. 2A to 11B are cross-sectional views and plan views illustrating a method of manufacturing a semiconductor device of the first embodiment;

FIGS. 12A and 12B are a cross-sectional view and a plan view illustrating the structure of a semiconductor manufacturing apparatus of the first embodiment;

FIG. 13 is a plan view illustrating a structure of an outer peripheral vacuum chuck of the first embodiment;

FIGS. 14A to 16B are cross-sectional views illustrating a method of manufacturing a semiconductor device of a first comparative example;

FIGS. 17A to 18B are cross-sectional views illustrating a method of manufacturing a semiconductor device of a second comparative example;

FIGS. 19A and 19B are a cross-sectional view and a plan view illustrating a structure of a semiconductor manufacturing apparatus of a second embodiment; and

FIG. 20 is a plan view illustrating a structure of an outer peripheral vacuum chuck of a second embodiment.

### DETAILED DESCRIPTION

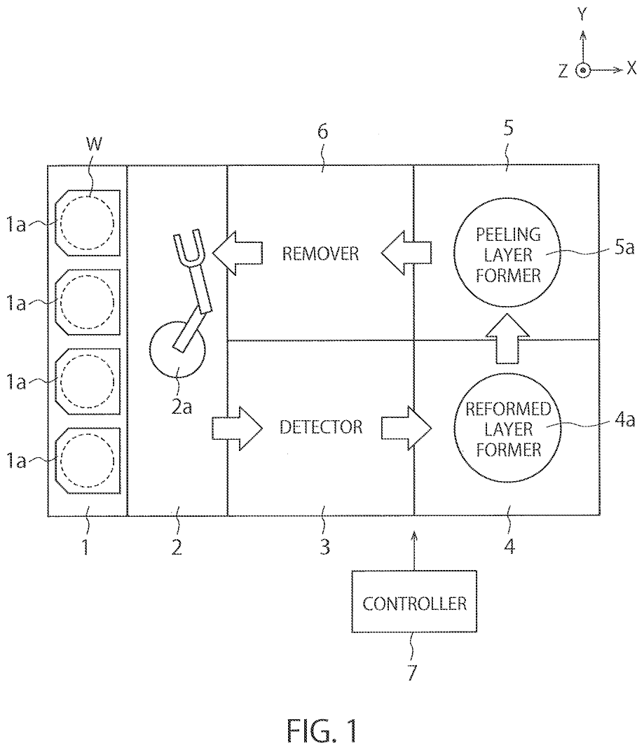

Embodiments will now be explained with reference to the accompanying drawings. In FIGS. 1 to 20, the same configurations are denoted by the same reference characters, and overlapping descriptions are omitted.

In one embodiment, a semiconductor manufacturing apparatus includes a reformed layer former configured to partially reform a first substrate to form a reformed layer between a first portion and a second portion in the first substrate, a peeling layer former configured to form a peeling layer between the second portion and a second substrate provided on a surface of the first substrate, and a remover configured to remove the second portion from a surface of the second substrate while causing the first portion to remain on the surface of the second substrate. The remover includes a heater configured to heat the first portion or the second portion, to peel the second portion from the second substrate at the peeling layer and divide the first portion and the second portion from each other, and a mover configured to move the second substrate relative to the second portion, to remove the second portion from the surface of the second substrate while causing the first portion to remain on the surface of the second substrate.

### First Embodiment

FIG. 1 is a plan view illustrating a structure of a semiconductor manufacturing apparatus of a first embodiment.

The semiconductor manufacturing apparatus of the present embodiment includes a placing portion 1, a carrier 2, a detector 3, a reformed layer former 4, a peeling layer former 5, a remover 6, and a controller 7. The placing portion 1 includes a plurality of load ports 1a, and the carrier 2 includes a carrying robot 2a. The reformed layer former 4 includes a chuck table 4a, and the peeling layer former 5 includes a chuck table 5a.

FIG. 1 illustrates an X direction, a Y direction, and a Z direction perpendicular to each other. In the present description, a +Z direction is treated as an upper direction, and a −Z direction is treated as a lower direction. The −Z direction may match with the gravity direction or may not match with the gravity direction.

The semiconductor manufacturing apparatus of the present embodiment is used in order to process a wafer W. As described below, the wafer W of the present embodiment includes a lower wafer and an upper wafer and has a structure in which those two wafers are bonded together. Further details of the wafer W are described below.

The placing portion 1 is used in order to place a front opening unified pod (FOUP) for housing the wafer W. When the wafer W is carried into a casing of the semiconductor manufacturing apparatus, the FOUP housing the wafer W is placed on any of the load ports 1a, and the wafer W is carried into the casing from the FOUP. Meanwhile, the wafer W carried out from the casing is housed in the FOUP on any of the load ports 1a.

The carrier 2 carries the wafer W in the casing by the carrying robot 2a. The detector 3 performs notch alignment of the wafer W carried by the carrier 2 and detects the center of the wafer W. The reformed layer former 4 places the wafer W carried from the detector 3 on the chuck table 4a and forms a reformed layer in the upper wafer included in the wafer W. The peeling layer former 5 places the wafer W carried from the reformed layer former 4 onto the chuck table 5a and forms a peeling layer between the upper wafer and the lower wafer in the wafer W. The remover 6 partially removes the upper wafer in the wafer W carried from the peeling layer former 5. The wafer W that has passed through the detector 3, the reformed layer former 4, the peeling layer former 5, and the remover 6 is carried out to a place outside of the casing by the carrier 2.

The controller 7 controls various operations of the semiconductor manufacturing apparatus of the present embodiment. For example, the controller 7 carries the wafer W by controlling the carrying robot 2a and rotates the wafer W by controlling the chuck tables 4a, 5a.

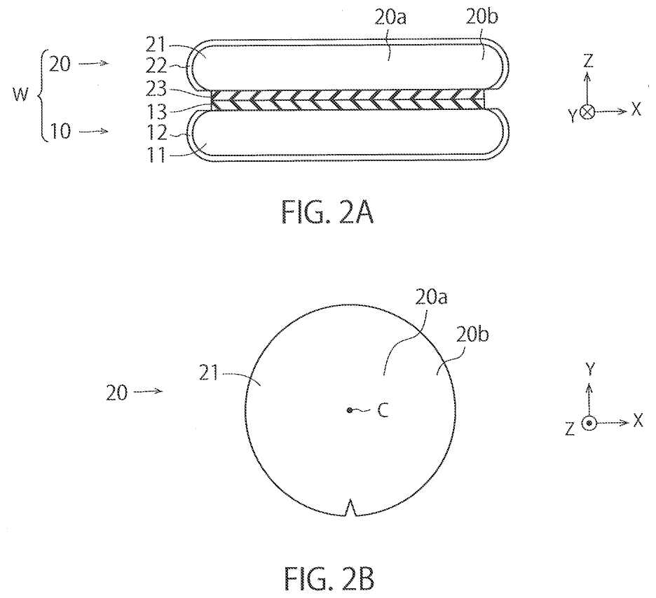

FIGS. 2A to 11B are cross-sectional views and plan views illustrating a method of manufacturing a semiconductor device of the first embodiment.

The semiconductor device of the present embodiment is manufactured from the wafer W illustrated in FIG. 1. A part of the method of manufacturing the semiconductor device of the present embodiment is executed with use of the semiconductor manufacturing apparatus illustrated in FIG. 1. Therefore, in the description below, reference characters indicated in FIG. 1 are used, as appropriate.

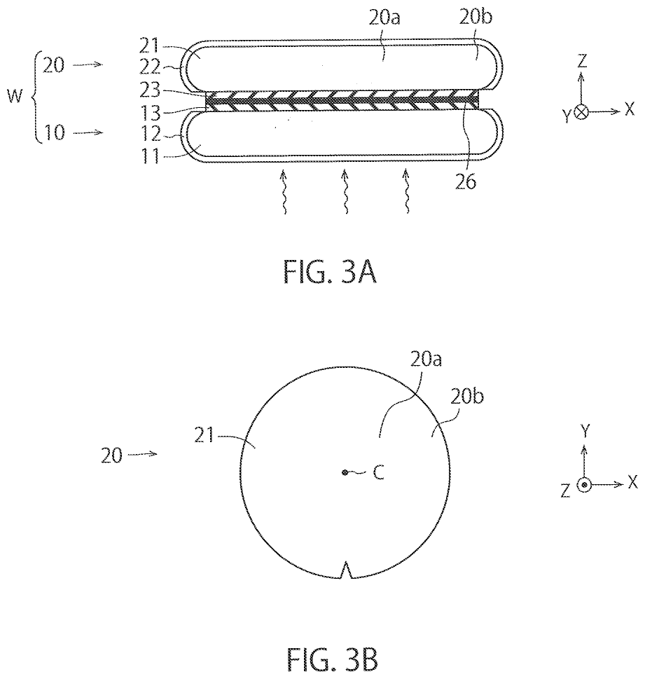

FIG. 2A illustrates a sectional shape of the wafer W, and FIG. 2B illustrates a planar shape of the wafer W. The same applies to FIG. 3A to 11B.

First, the wafer W illustrated in FIGS. 2A and 2B is prepared. As described above, the wafer W of the present embodiment includes a lower wafer 10 and an upper wafer 20 and has a structure in which a surface (upper face) of the lower wafer 10 and a surface (lower face) of the upper wafer 20 are bonded together. The upper wafer 20 is an example of a first substrate. The lower wafer 10 is an example of a second substrate.

The lower wafer 10 includes a semiconductor wafer 11, a film 12 formed on a lower face and a side face of the semiconductor wafer 11, and a film 13 formed on an upper face of the semiconductor wafer 11. The upper wafer 20 includes a semiconductor wafer 21, a film 22 formed on an upper face and a side face of the semiconductor wafer 21, and a film 23 formed on a lower face of the semiconductor wafer 21. The upper wafer 20 is placed on the lower wafer 10 in a form in which the film 13 and the film 23 are bonded together.

Each of the semiconductor wafers 11, 21 is a silicon wafer, for example. Each of the films 13, 23 includes various insulators such as an inter layer dielectric, an interconnect layer, a plug layer, and a pad layer, a semiconductor layer, and a conductor layer, for example. The films 13, 23 may include devices such as a memory cell array and a transistor, for example. The films 13, 23 of the present embodiment each include a silicon oxide film on an interface between the film 13 and the film 23, and the silicon oxide film in the film 13 and the silicon oxide film in the film 23 are bonded together.

FIGS. 2A and 2B illustrate a center C of the upper wafer 20, a central portion 20a that is a portion on the center C side in the upper wafer 20, and an outer peripheral portion 20b that is a portion on the side opposite to the center C in the upper wafer 20. The center of the lower wafer 10 is positioned substantially directly below (in the −Z direction of) the center C of the upper wafer 20. In the method of manufacturing the semiconductor device of the present embodiment, the outer peripheral portion 20b of the upper wafer 20 is removed from the wafer W by a process described below. The central portion 20a is an example of a first portion, and the outer peripheral portion 20b is an example of a second portion.

Next, the wafer W is annealed (FIGS. 3A and 3B). As a result, the lower face of the film 23 is bonded to the upper face of the film 13, and a bonding layer 26 is formed near the interface between the film 13 and the film 23 in the films 13, 23. As above, the lower wafer 10 and the upper wafer 20 are bonded together by the bonding layer 26.

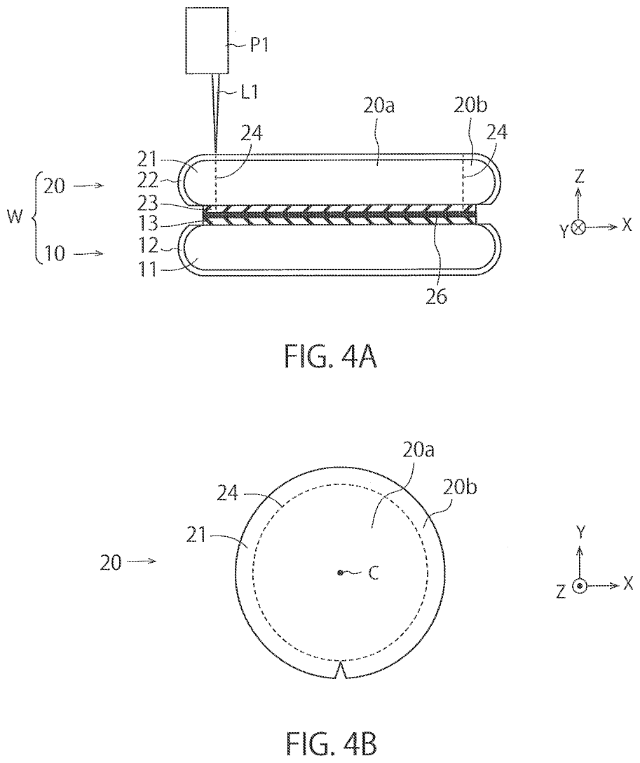

Next, the upper wafer 20 is partially reformed, and a reformed layer 24 is formed between the central portion 20a and the outer peripheral portion 20b in the upper wafer 20 (FIGS. 4A and 4B). FIG. 4A illustrates an emitter P1 that is provided in the reformed layer former 4 and that emits a laser L1. The reformed layer 24 of the present embodiment is formed by irradiating the upper wafer 20 with the laser L1 and is specifically formed in a section irradiated with the laser L1. In the present embodiment, a section irradiated with the laser L1 is amorphized, and mono silicon in the semiconductor wafer 21 is changed to amorphous silicon, for example. Therefore, an amorphous layer is formed as the reformed layer 24.

As illustrated in FIG. 4A, the reformed layer 24 of the present embodiment is formed so as to extend in the upper wafer 20 in the −Z direction and pass through the upper wafer 20. As illustrated in FIG. 4B, the reformed layer 24 of the present embodiment is formed in the upper wafer 20 so as to have a ring planar shape. Therefore, the central portion 20a illustrated in FIG. 4B, in other words, a portion on the inner side of the reformed layer 24 in the upper wafer 20 has a circular planar shape. Meanwhile, the outer peripheral portion 20b illustrated in FIG. 4B, in other words, a portion on the outer side of the reformed layer 24 in the upper wafer 20 has a ring-like planar shape and surrounds the central portion 20a in a ring manner. The reformed layer 24 is formed by placing the wafer W on the chuck table 4a and irradiating the wafer W with the laser L1 while rotating the chuck table 4a, for example. It is desired that the wavelength of the laser L1 be set to a value at which the laser L1 is not absorbed by the semiconductor wafer 21 and is set to 1117 nm or more, for example.

The reformed layer 24 may be formed so as to have a shape different from the shape illustrated in FIGS. 4A and 4B. For example, the reformed layer 24 may be formed such that the planar shape of the central portion 20a becomes a shape other than the circular shape. When the planar shape of the central portion 20a is a circular shape, the value of the diameter of the central portion 20a may be set to any value in accordance with the size of the outer peripheral portion 20b desired to be removed from the wafer W. For example, the size of the semiconductor wafer 21 in the outer peripheral portion 20b may be larger or smaller than the size of a bevel portion of the semiconductor wafer 21. In this case, the distance between the innermost periphery and the outermost periphery of the outer peripheral portion 20b is from 1 mm to 6 mm, for example. The reformed layer 24 is formed after the bonding of the upper wafer 20 and the lower wafer 10 in the present embodiment but may be formed before the bonding instead.

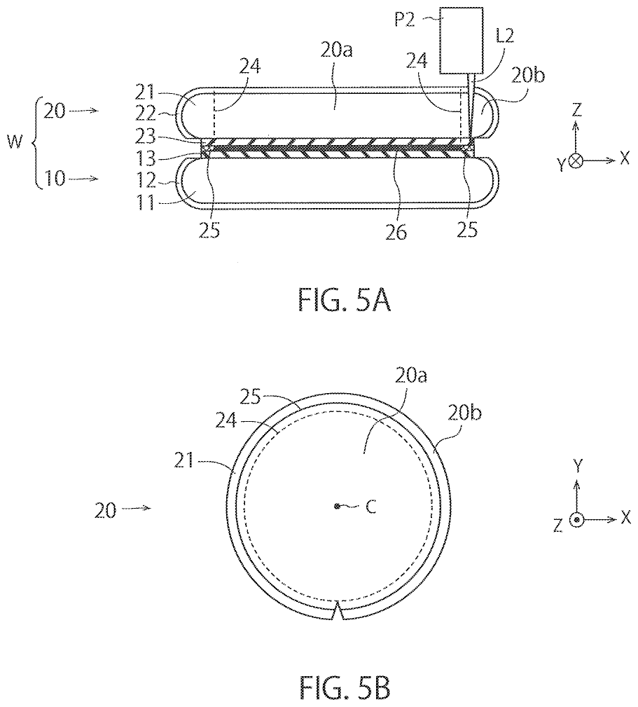

Next, a peeling layer 25 for peeling the outer peripheral portion 20b from the lower wafer 10 is formed between the lower wafer 10 and the outer peripheral portion 20b (FIGS. 5A and 5B). FIG. 5A illustrates an emitter P2 that is provided in the peeling layer former 5 and that emits a laser L2. The peeling layer 25 of the present embodiment is formed by irradiating the films 13, 23 with the laser L2, and is specifically formed in a section irradiated with the laser L2. The peeling layer 25 of the present embodiment is formed by causing the laser L2 to be absorbed by the films 13, 23. Therefore, it is desired that the interface of the films 13, 23 of the present embodiment be formed by a material that absorbs the laser L2. An example of such material is a silicon oxide film. It is desired that the wavelength of the laser L2 be set to a value at which the laser L2 is absorbed by the films 13, 23.

As illustrated in FIG. 5A, the peeling layer 25 of the present embodiment is formed near the interface between the film 13 and the film 23 in the films 13, 23. As illustrated in FIG. 5B, the peeling layer 25 of the present embodiment is formed so as to have a ring-like planar shape. The peeling layer 25 is formed between the lower wafer 10 and the outer peripheral portion 20b, and hence is formed on the side opposite to the center C with respect to the reformed layer 24. The peeling layer 25 of the present embodiment is formed near the reformed layer 24. The peeling layer 25 of the present embodiment is formed only in the outer peripheral portion 20b out of the central portion 20a and the outer peripheral portion 20b. This makes it possible to easily peel the outer peripheral portion 20b from the lower wafer 10. The peeling layer 25 is formed by placing the wafer W on the chuck table 5a and irradiating the wafer W with the laser L2 while rotating the chuck table 5a, for example.

The peeling layer 25 may be formed so as to have a shape different from the shape illustrated in FIGS. 5A and 5B. The peeling layer 25 is formed after the reformed layer 24 is formed in the present embodiment but may be formed before the reformed layer 24 is formed instead. When the film 13 includes a laminated film including a plurality of layers, the peeling layer 25 may be formed between any two layers in the laminated film. Similarly, when the film 23 includes a laminated film including a plurality of layers, the peeling layer 25 may be formed between any two layers in the laminated film.

The annealing illustrated in FIGS. 3A and 3B may be performed such that only the central portion 20a out of the central portion 20a and the outer peripheral portion 20b is annealed. In this case, the bonding layer 26 is formed near the interface between the film 13 and the film 23 in the central portion 20a, but the bonding layer 26 is not formed near the interface between the film 13 and the film 23 in the outer peripheral portion 20b. Therefore, the outer peripheral portion 20b is easily peeled from the lower wafer 10 even after the annealing. Therefore, in this case, the process illustrated in FIGS. 5A and 5B may be omitted.

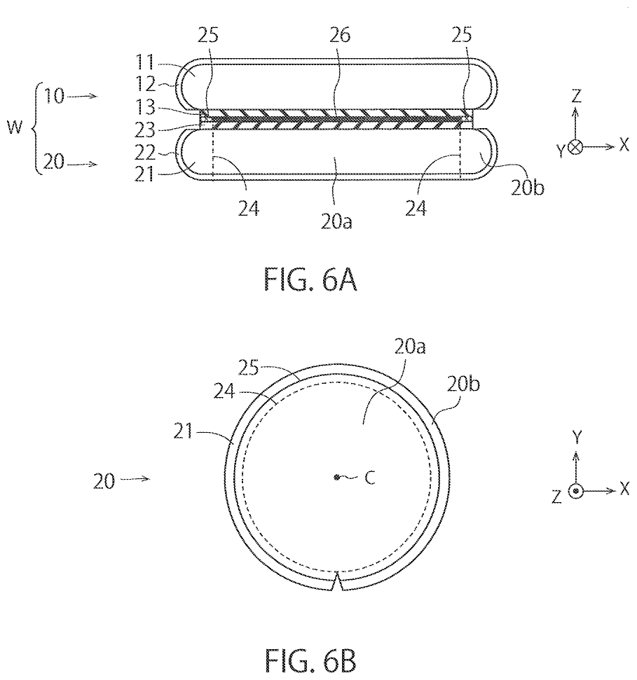

Next, the orientation of the wafer W is reversed (FIGS. 6A and 6B). As a result, the wafer W illustrated in FIG. 6A includes the upper wafer 20 on the lower side in the wafer W and includes the lower wafer 10 on the upper side in the wafer W. The remover 6 of the present embodiment includes a reverser (not shown), and the reverser reverses the orientation of the wafer W that has been carried to the remover 6 from the peeling layer former 5.

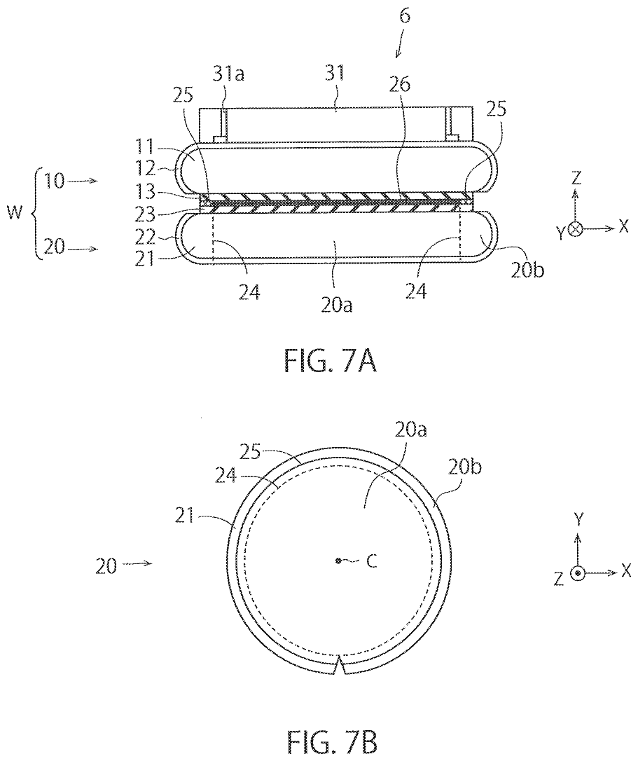

Next, the wafer W is held by adsorbing the wafer W by an upper vacuum chuck 31 in the remover 6 (FIGS. 7A and 7B). The upper vacuum chuck 31 can hold the lower wafer 10 by adsorption by coming into contact with the lower wafer 10 from a place above the lower wafer 10. The upper vacuum chuck 31 can move the lower wafer 10 that is held by adsorption. The lower wafer 10 is bonded to the upper wafer 20, and hence the upper vacuum chuck 31 can move the upper wafer 20 together with the lower wafer 10. The upper vacuum chuck 31 is an example of a first holder of a mover.

The upper vacuum chuck 31 includes a vacuum trench 31a and holds the lower wafer 10 by an adsorption force from the vacuum trench 31a. The upper vacuum chuck 31 may further include a cooling mechanism that cools the lower wafer 10. This makes it possible to cool the lower wafer 10 held by the upper vacuum chuck 31 by the cooling mechanism. The cooling mechanism cools the lower wafer 10 with use of cooling fluid such as liquid nitrogen, for example. The cooling mechanism may also indirectly cool the upper wafer 20 by cooling the lower wafer 10.

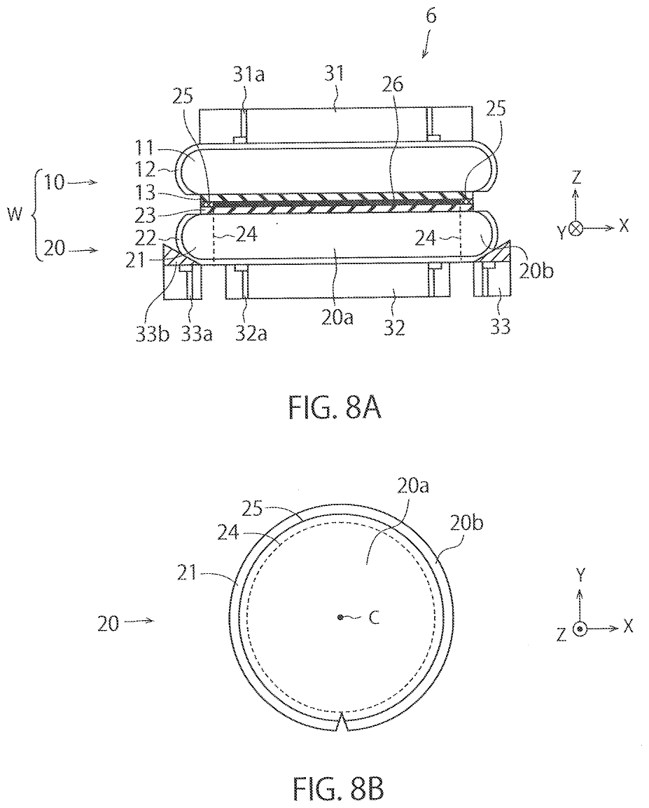

Next, the wafer W is moved by the upper vacuum chuck 31, and the wafer W is placed on a central vacuum chuck 32 and an outer peripheral vacuum chuck 33 (FIGS. 8A and 8B). The remover 6 includes one upper vacuum chuck 31 for holding the lower wafer 10, and two lower vacuum chucks (the central vacuum chuck 32 and the outer peripheral vacuum chuck 33) for holding the upper wafer 20. The central vacuum chuck 32 can hold the central portion 20a by adsorption by coming into contact with the central portion 20a. The outer peripheral vacuum chuck 33 can hold the outer peripheral portion 20b by adsorption by coming into contact with the outer peripheral portion 20b. The central vacuum chuck 32 is an example of a second holder of the mover. The outer peripheral vacuum chuck 33 is an example of a third holder of the mover.

The central vacuum chuck 32 includes a vacuum trench 32a and holds the central portion 20a by an adsorption force from the vacuum trench 32a. The central vacuum chuck 32 may further include a cooling mechanism that cools the central portion 20a. This makes it possible to cool the central portion 20a held by the central vacuum chuck 32 by the cooling mechanism. The cooling mechanism cools the central portion 20a with use of cooling fluid such as liquid nitrogen, for example. The cooling mechanism may also indirectly cool the lower wafer 10 by cooling the central portion 20a.

The outer peripheral vacuum chuck 33 includes a vacuum trench 33a and holds the outer peripheral portion 20b by an adsorption force from the vacuum trench 33a. The outer peripheral vacuum chuck 33 further includes a heater 33b that heats the outer peripheral portion 20b. This makes it possible to heat the outer peripheral portion 20b held by the outer peripheral vacuum chuck 33 by the heater 33b. In the present embodiment, the temperature of the heater 33b is preset to a high temperature before the wafer W is placed on the outer peripheral vacuum chuck 33. Therefore, when the wafer W is placed on the outer peripheral vacuum chuck 33, the outer peripheral portion 20b is more speedily heated by the heater 33b, and the temperature of the outer peripheral portion 20b rapidly rises. As illustrated in FIG. 8A, the outer peripheral portion 20b of the present embodiment is placed on the heater 33b. The upper face of the heater 33b of the present embodiment is tilted with respect to the XY plane in order to easily hold the outer peripheral portion 20b and easily come into contact with the outer peripheral portion 20b.

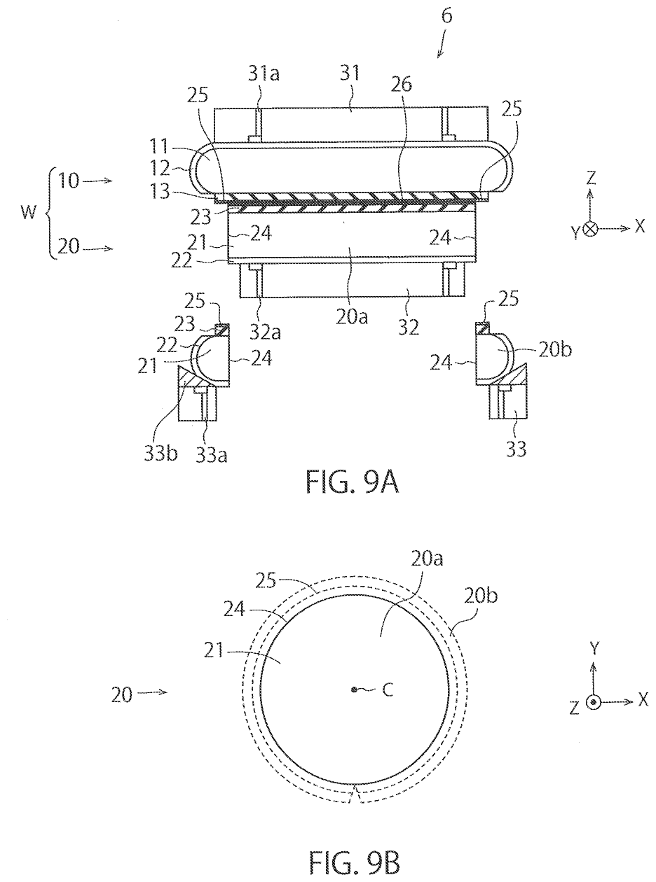

In the present embodiment, a temperature difference is generated between the outer peripheral portion 20b and the central portion 20a by heating the outer peripheral portion 20b and cooling the central portion 20a. As a result, a thermal stress is generated between the outer peripheral portion 20b and the central portion 20a, and a crack grows in the reformed layer 24. This makes it possible to divide the outer peripheral portion 20b and the central portion 20a from each other. The wafer W of the present embodiment includes the peeling layer 25 between the outer peripheral portion 20b and the lower wafer 10. Therefore, the outer peripheral portion 20b is easily peeled from the lower wafer 10. Therefore, the present embodiment makes it possible to divide the outer peripheral portion 20b and the central portion 20a from each other by thermal stress and peel the outer peripheral portion 20b from the lower wafer 10 at the peeling layer 25 (FIGS. 9A and 9B).

The remover 6 of the present embodiment heats the outer peripheral portion 20b by the heater 33b such that the temperature of the outer peripheral portion 20b becomes higher than the temperature of the central portion 20a, and the central portion 20a and the lower wafer 10 are cooled by the abovementioned cooling mechanism. It is desired that the heating and the cooling be performed such that the temperature difference between the outer peripheral portion 20b and the central portion 20a be 200° C. to 400° C. This makes it possible to sufficiently increase the difference in the expansion and contraction amount between the outer peripheral portion 20b and the central portion 20a and generate a sufficient thermal stress between the outer peripheral portion 20b and the central portion 20a. For example, the difference in the expansion and contraction amount between the outer peripheral portion 20b and the central portion 20a when the semiconductor wafer 21 is a silicon substrate becomes from about 0.2 mm to about 0.5 mm in accordance with the temperature difference of 200° C. to 400° C.

The temperature difference between the outer peripheral portion 20b and the central portion 20a may be generated by heating by the heater 33b and cooling by the abovementioned cooling mechanism or may be generated by only the heating by the heater 33b. The method of the former has an advantage in that it becomes unnecessary to cause the temperature of the outer peripheral portion 20b to be extremely high, for example. The method of the latter has an advantage in that the abovementioned cooling mechanism becomes unnecessary in the remover 6. When the method of the latter is employed, the temperature of the central portion 20a that is not cooled becomes room temperature. Similarly, the temperature of the lower wafer 10 that is not cooled also becomes room temperature. The temperature difference between the outer peripheral portion 20b and the central portion 20a may be realized by only heating the central portion 20a or may be realized by heating the central portion 20a and cooling the outer peripheral portion 20b.

Then, the remover 6 of the present embodiment raises the upper vacuum chuck 31 and the central vacuum chuck 32 in the upper direction (+Z direction) in a state in which the upper vacuum chuck 31, the central vacuum chuck 32, and the outer peripheral vacuum chuck 33 are holding the lower wafer 10, the central portion 20a, and the outer peripheral portion 20b by adsorption (FIGS. 9A and 9B). In other words, the upper vacuum chuck 31 and the central vacuum chuck 32 are moved relative to the outer peripheral vacuum chuck 33. As a result, the lower wafer 10 and the central portion 20a rise in a state of being sandwiched between the upper vacuum chuck 31 and the central vacuum chuck 32 and are separated from the outer peripheral portion 20b. This makes it possible to remove the outer peripheral portion 20b from the surface of the lower wafer 10 while causing the central portion 20a to remain on the surface of the lower wafer 10. In other words, it becomes possible to trim the wafer W such that the outer peripheral portion 20b is removed.

The adsorption of the outer peripheral portion 20b by the outer peripheral vacuum chuck 33 has an advantage in that the lower wafer 10 and the central portion 20a are easily separated from the outer peripheral portion 20b and an advantage in that the outer peripheral portion 20b after the separation can be prevented from breaking by falling from the outer peripheral vacuum chuck 33, for example. The cooling of the lower wafer 10 has an advantage in that a case where the abovementioned crack grows to the lower wafer 10 can be suppressed and an advantage in that the peeling between the lower wafer 10 and the central portion 20a can be suppressed, for example.

The reformed layer 24 extends to be parallel to the Z direction in the present embodiment but may be tilted with respect to the Z direction. For example, the reformed layer 24 may be tilted with respect to the Z direction such that the diameter of the central portion 20a becomes larger on the side of the film 23 and becomes smaller on the side opposite to the film 23. As a result, the central portion 20a having a circular planar shape easily comes off from the outer peripheral portion 20b having a ring-like planar shape, and the central portion 20a is easily separated from the outer peripheral portion 20b. In this case, an outer peripheral face of the central portion 20a and an inner peripheral face of the outer peripheral portion 20b are tapered faces.

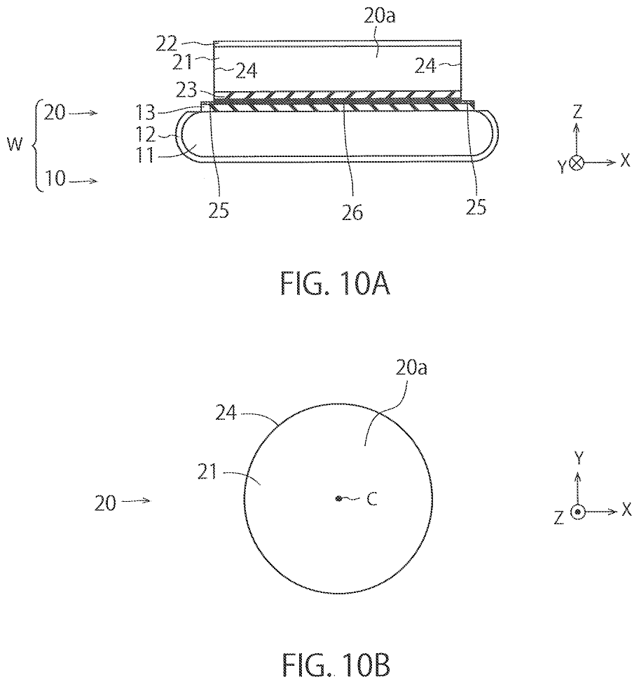

Next, the orientation of the wafer W is reversed again (FIGS. 10A and 10B). As a result, the wafer W illustrated in FIG. 10A includes the lower wafer 10 on the lower side in the wafer W and includes the upper wafer 20 (central portion 20a) on the upper side in the wafer W. In the remover 6 of the present embodiment, the abovementioned reverser reverses the orientation of the wafer W after the trimming.

Then, the wafer W of the present embodiment is carried out to a place outside of the casing of the semiconductor manufacturing apparatus by the carrying robot 2a. The outer peripheral portion 20b removed from the wafer W is also carried out to a place outside of the casing of by the carrying robot 2a. The carrying robot 2a is an example of a carrying mechanism. In general trimming, the outer peripheral portion 20b is removed by shaving the outer peripheral portion 20b. Therefore, the outer peripheral portion 20b is removed from the wafer W by turning into a large amount of powder. Meanwhile, in the trimming of the present embodiment, the outer peripheral portion 20b is removed by dividing the outer peripheral portion 20b from the central portion 20a and peeling the outer peripheral portion 20b from the lower wafer 10. Therefore, the outer peripheral portion 20b is removed from the wafer W without turning into a large amount of powder. Therefore, the present embodiment makes it possible to easily carry out the outer peripheral portion 20b from the casing by the carrying robot 2a and suppress the time and effort of removing a large amount of powder from the casing. The semiconductor manufacturing apparatus of the present embodiment may carry out the outer peripheral portion 20b to a place outside of the casing by a carrying mechanism other than the carrying robot 2a. The outer peripheral portion 20b is collected into the FOUP, for example.

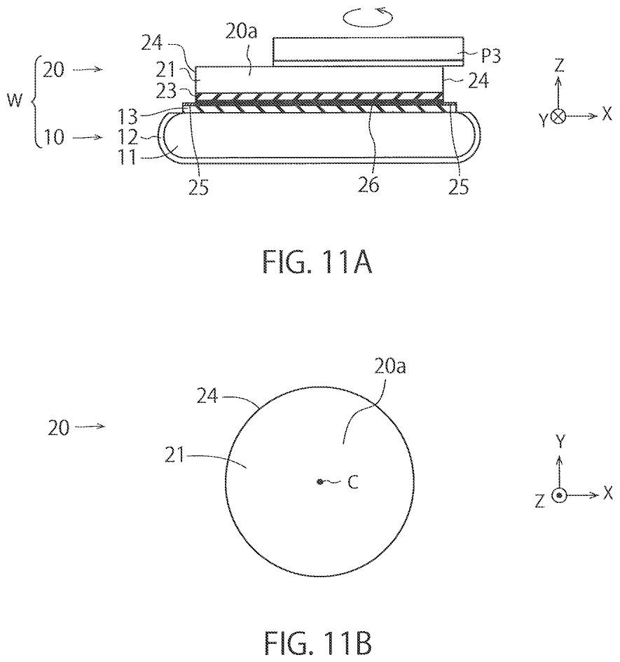

Next, the upper face of the upper wafer 20 is ground by a grinder P3 (FIGS. 11A and 11B). As a result, the upper wafer 20 is thinned. The process illustrated in FIGS. 11A and 11B is performed by an apparatus other than the semiconductor manufacturing apparatus of the present embodiment.

Then, the wafer W is processed by various processes. The semiconductor device of the present embodiment is manufactured as above. The semiconductor device of the present embodiment is a three-dimensional semiconductor memory, for example.

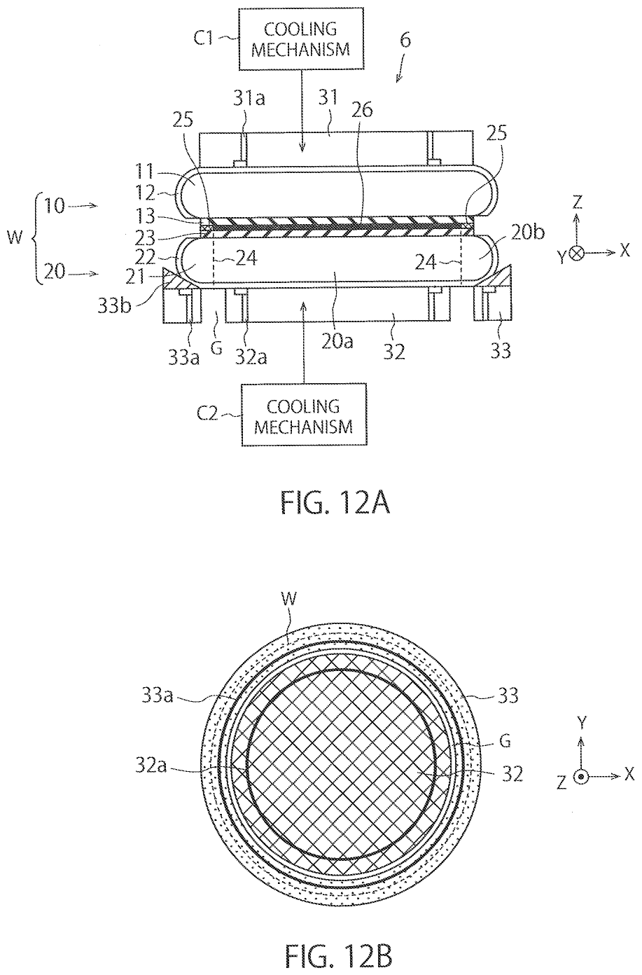

FIGS. 12A and 12B are a cross-sectional view and a plan view illustrating the structure of the semiconductor manufacturing apparatus of the first embodiment. Specifically, FIGS. 12A and 12B are a cross-sectional view and a plan view illustrating the structure of the remover 6 in the semiconductor manufacturing apparatus of the present embodiment, respectively.

As illustrated in FIG. 12A, the remover 6 of the present embodiment includes the upper vacuum chuck 31, the central vacuum chuck 32, and the outer peripheral vacuum chuck 33 described above. The upper vacuum chuck 31 includes the vacuum trench 31a. The central vacuum chuck 32 includes the vacuum trench 32a. The outer peripheral vacuum chuck 33 includes the vacuum trench 33a and the heater 33b. FIG. 12A illustrates the wafer W in the process illustrated in FIGS. 8A and 8B. FIG. 12A further illustrates the abovementioned cooling mechanism included in the upper vacuum chuck 31 with a reference character C1 and illustrates the abovementioned cooling mechanism included in the central vacuum chuck 32 with a reference character C2.

The central vacuum chuck 32 and the outer peripheral vacuum chuck 33 are separated from each other over a gap G. The gap G of the present embodiment is filled with air. This makes it possible to improve heat insulating properties between the central vacuum chuck 32 and the outer peripheral vacuum chuck 33. Meanwhile, the remover 6 may include some kind of member (for example, a heat insulating material) in the gap G.

FIG. 12B illustrates the planar shape of the central vacuum chuck 32 by cross-hatching, illustrates the planar shape of the outer peripheral vacuum chuck 33 by dot-hatching, and illustrates the planar shape of the gap G to be outlined and white. FIG. 12B further illustrates the positions of the vacuum trenches 32a, 33a by thick solid lines and illustrates the outline of the wafer W by a broken line.

As illustrated in FIG. 12B, the central vacuum chuck 32 has a circular shape in planar view so as to easily hold the central portion 20a. Meanwhile, the outer peripheral vacuum chuck 33 has a ring shape in planar view so as to easily hold the outer peripheral portion 20b and surrounds the central portion 20a in a ring manner. The vacuum trench 32a extends in the central vacuum chuck 32 along a circle, and the vacuum trench 33a extends in the outer peripheral vacuum chuck 33 along a circle. The same applies to the vacuum trench 31a. The vacuum trench 31a extends in the upper vacuum chuck 31 along a circle (FIG. 12A).

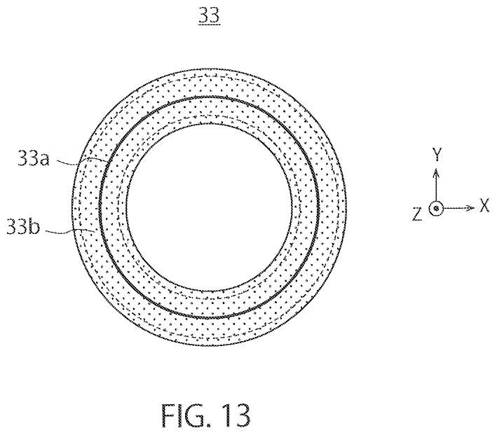

FIG. 13 is a plan view illustrating a structure of the outer peripheral vacuum chuck 33 of the first embodiment.

As with FIG. 12B, FIG. 13 illustrates the planar shape of the outer peripheral vacuum chuck 33 by dot-hatching. FIG. 13 further illustrates the positions of the vacuum trench 33a by a thick solid line and illustrates the outline of the heater 33b by a broken line. As illustrated in FIG. 13, the heater 33b of the present embodiment has a ring shape in planar view so as to easily heat the outer peripheral portion 20b. This makes it possible to speedily heat the entire outer peripheral portion 20b.

Next, the method of manufacturing the semiconductor device of the present embodiment is compared with methods of manufacturing a semiconductor device of a first comparative example and a second comparative example.

### (1) First Comparative Example

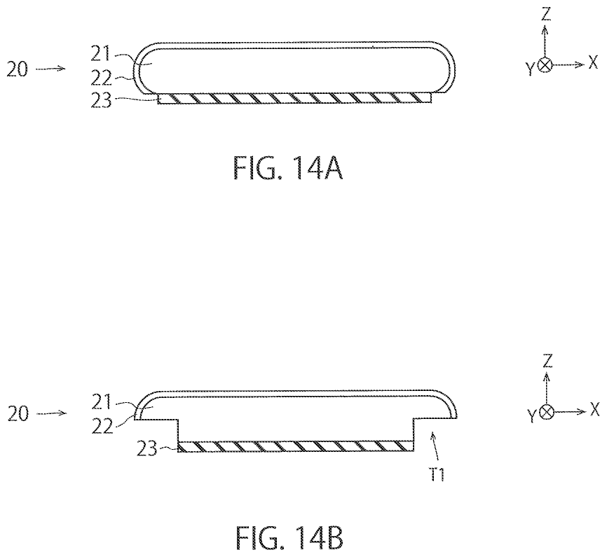

FIGS. 14A to 16B are cross-sectional views illustrating the method of manufacturing the semiconductor device of the first comparative example of the first embodiment. In the present comparative example, the upper wafer 20 is trimmed before the lower wafer 10 and the upper wafer 20 are bonded together.

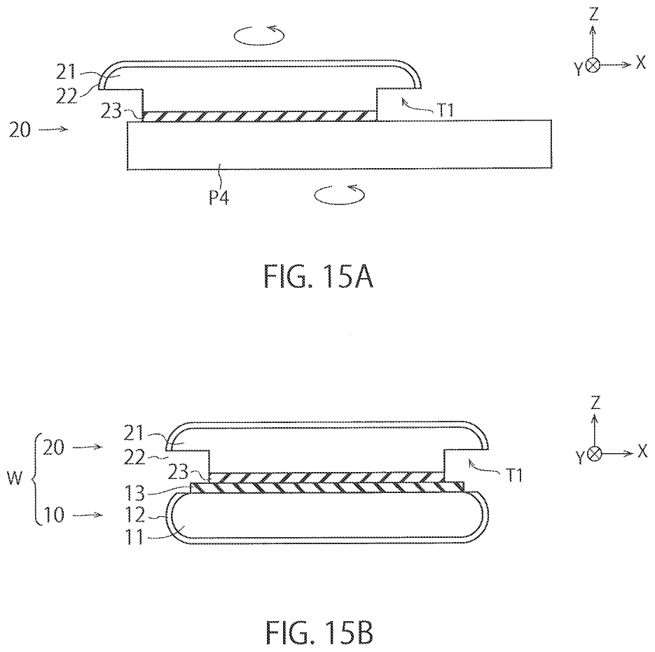

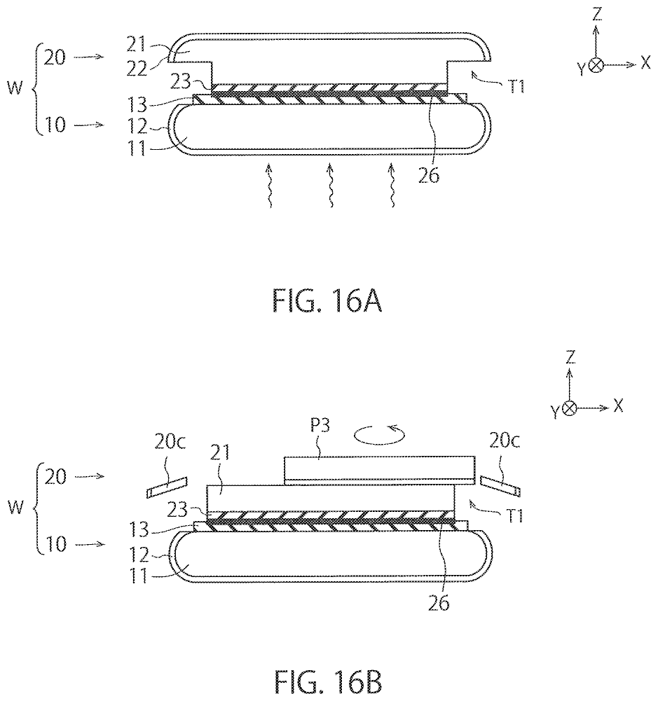

First, the upper wafer 20 illustrated in FIG. 14A is prepared, and the upper wafer 20 is trimmed as illustrated in FIG. 14B. FIG. 14B illustrates a trimming portion T1 of the upper wafer 20. Next, the film 23 in the upper wafer 20 is polished with use of a chemical mechanical polishing (CMP) apparatus P4 (FIG. 15A). Then, the upper wafer 20 is bonded to the lower wafer 10 (FIG. 15B). Next, the lower face of the film 23 is bonded to the upper face of the film 13 by annealing the wafer W (FIG. 16A). Next, the upper wafer 20 is thinned by grinding the upper face of the upper wafer 20 by the grinder P3 (FIG. 16B). At this time, parts on the trimming portion T1 in the upper wafer 20 become offcuts 20c.

In the present comparative example, when the upper wafer 20 is trimmed in the process in FIG. 14B, the trimming portion T1 turns into a large amount of powder. In the present comparative example, there is a fear that edges of the film 23 are excessively polished when the film 23 is polished in the process in FIG. 15A. However, when the film 23 is not polished, there is a fear that the influence of the trimming remains on the film 23. In the present comparative example, burdensome processing for collecting the offcuts 20c is necessary. Meanwhile, the present embodiment makes it possible to suppress those problems.

### (2) Second Comparative Example

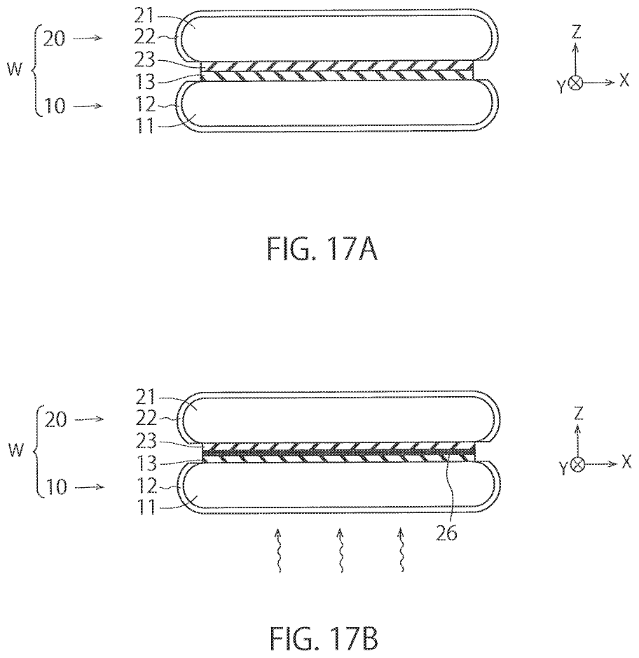

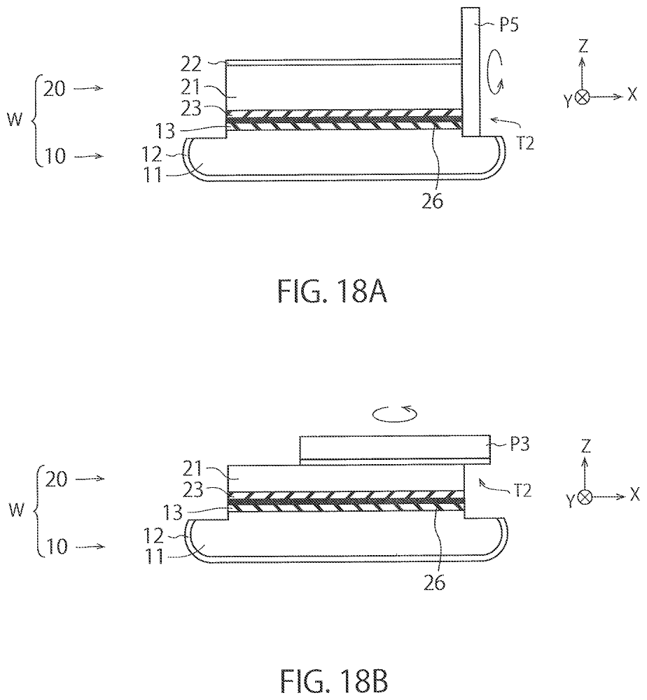

FIGS. 17A to 18B are cross-sectional views illustrating the method of manufacturing the semiconductor device of the second comparative example of the first embodiment. In the present comparative example, the upper wafer 20 is trimmed after the lower wafer 10 and the upper wafer 20 are bonded together.

First, the upper wafer 20 is bonded to the lower wafer 10 (FIG. 17A). Next, the lower face of the film 23 is bonded to the upper face of the film 13 by annealing the wafer W (FIG. 17B). Next, the upper wafer 20 is trimmed by a blade P5 (FIG. 18A). FIG. 18A illustrates a trimming portion T2 of the upper wafer 20. Next, the upper wafer 20 is thinned by grinding the upper face of the upper wafer 20 by the grinder P3 (FIG. 18B).

In the present comparative example, when the upper wafer 20 is trimmed in the process in FIG. 18A, the trimming portion T2 turns into a large amount of powder. In the present comparative example, there is a fear that not only the upper wafer 20 but also the lower wafer 10 is trimmed when the upper wafer 20 is trimmed in the process of FIG. 18A. Meanwhile, the present embodiment makes it possible to suppress those problems.

In the trimming of the wafer W of the present embodiment, the reformed layer 24 and the peeling layer 25 are formed in the wafer W, and the outer peripheral portion 20b in the wafer W is heated (see FIGS. 8A and 8B). As a result, the outer peripheral portion 20b can be removed from the wafer W by dividing the outer peripheral portion 20b from the central portion 20a and peeling the outer peripheral portion 20b from the lower wafer 10 (see FIGS. 9A and 9B). Therefore, as described above, the present embodiment makes it possible to remove the outer peripheral portion 20b from the wafer W without turning the outer peripheral portion 20b into a large amount of powder.

Meanwhile, the trimming of the wafer W can be conceived to be performed by inserting a blade between the lower wafer 10 and the upper wafer 20 instead of heating the outer peripheral portion 20b in the wafer W. In other words, the trimming of the wafer W can be conceived to be realized by a mechanical force applied from the blade instead of a thermal stress generated by heating. According to the trimming by the blade, as with the trimming by thermal stress, it becomes possible to remove the outer peripheral portion 20b from the wafer W without turning the outer peripheral portion 20b into a large amount of powder. However, according to the trimming by the blade, there are a fear that the peeling between the lower wafer 10 and the upper wafer 20 progresses to the central portion 20a and a fear that an excessive force is applied to the wafer W and chipping occurs when the blade is not suitably operated. The present embodiment also makes it possible to suppress those problems.

As above, in the present embodiment, by heating the wafer W, the outer peripheral portion 20b is divided from the central portion 20a, and the outer peripheral portion 20b is peeled from the lower wafer 10. Therefore, the present embodiment makes it possible to suitably process the wafer W. For example, the present embodiment makes it possible to easily remove the outer peripheral portion 20b from the wafer W without turning the outer peripheral portion 20b into a large amount of powder.

### Second Embodiment

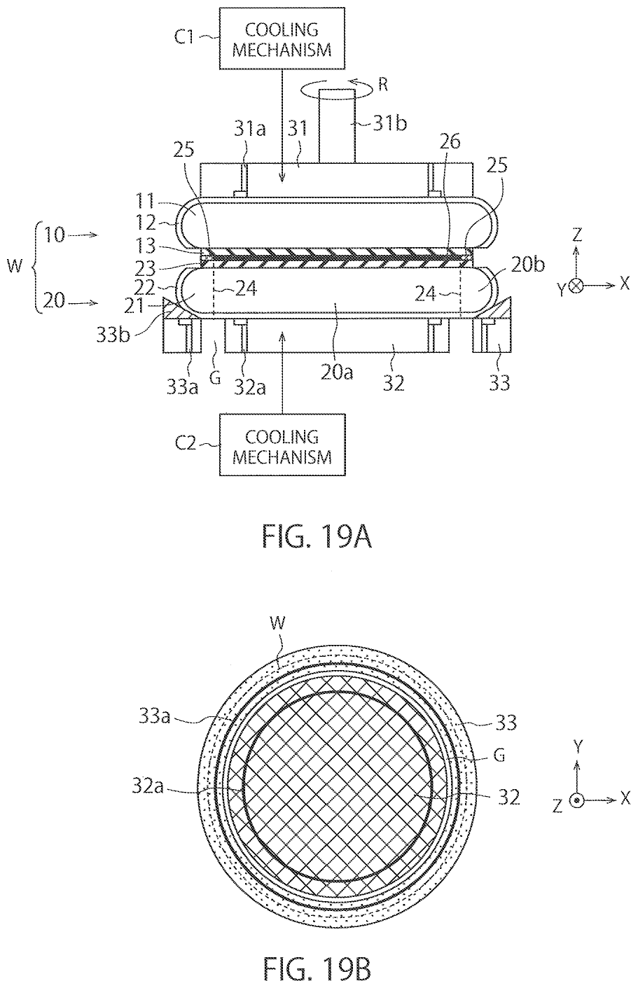

FIGS. 19A and 19B are a cross-sectional view and a plan view illustrating the structure of a semiconductor manufacturing apparatus of the second embodiment.

As with the semiconductor manufacturing apparatus of the first embodiment, the semiconductor manufacturing apparatus of the present embodiment has the structure illustrated in FIG. 1 and is used to execute a part of the method illustrated in FIGS. 2A to 11B. Meanwhile, while the remover 6 of the semiconductor manufacturing apparatus of the first embodiment has the structure illustrated in FIGS. 12A and 12B, the remover 6 of the semiconductor manufacturing apparatus of the present embodiment has a structure illustrated in FIGS. 19A and 19B. FIGS. 19A and 19B are a cross-sectional view and a plan view illustrating the structure of the remover 6 of the present embodiment, respectively.

The remover 6 of the present embodiment is different from the remover 6 of the first embodiment in the following two points. First, the upper vacuum chuck 31 of the present embodiment includes a rotational shaft 31b that rotates the upper vacuum chuck 31. The remover 6 of the present embodiment can rotate the wafer W held by the upper vacuum chuck 31 by rotating the upper vacuum chuck 31. Second, the outer peripheral vacuum chuck 33 of the present embodiment includes a plurality of the heaters 33b described below. The remover 6 of the present embodiment can heat the outer peripheral portion 20b by those heaters 33b while rotating the wafer W by the rotational shaft 31b.

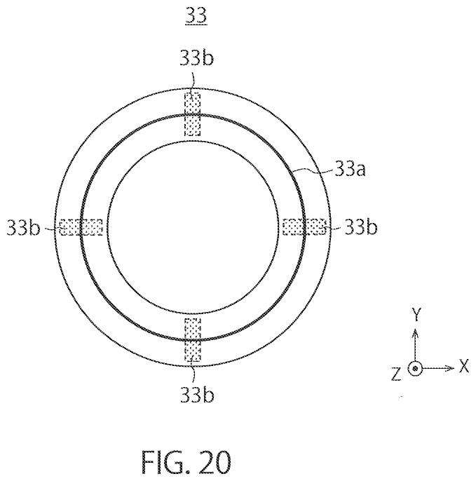

FIG. 20 is a plan view illustrating a structure of the outer peripheral vacuum chuck 33 of the second embodiment.

As illustrated in FIG. 20, the outer peripheral vacuum chuck 33 of the present embodiment includes the plurality of the heaters 33b. The number of the heaters 33b is four in the present embodiment but may be other than four. The planar shape of each of the heaters 33b is a quadrangle in the present embodiment but may be other shapes. For example, the outer peripheral vacuum chuck 33 may include the plurality of heaters 33b having arc-shaped (fan-shaped) planar shapes or only one heater 33b having an arc-shaped (fan-shaped) planar shape may be included.

If the outer peripheral portion 20b is heated without rotating the wafer W of the present embodiment, unevenness in the temperature of the outer peripheral portion 20b is easily generated. For example, in a section close to any of the heaters 33b in the outer peripheral portion 20b, the temperature of the section easily becomes high. Meanwhile, in a section far from all of the heaters 33b in the outer peripheral portion 20b, the temperature of the section easily becomes low. However, the wafer W of the present embodiment is heated while being rotated. Therefore, it becomes possible to suppress the generation of unevenness of the temperature in the outer peripheral portion 20b.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a reformed layer former configured to partially reform a first substrate to form a reformed layer between a first portion and a second portion in the first substrate;
a peeling layer former configured to form a peeling layer between the second portion and a second substrate provided on a surface of the first substrate; and
a remover configured to remove the second portion from a surface of the second substrate while causing the first portion to remain on the surface of the second substrate,
wherein the remover comprises:
a heater configured to heat the first portion or the second portion, to peel the second portion from the second substrate at the peeling layer and divide the first portion and the second portion from each other, and
a mover configured to move the second substrate relative to the second portion, to remove the second portion from the surface of the second substrate while causing the first portion to remain on the surface of the second substrate.

2. The apparatus of claim 1, wherein the second portion has a shape that surrounds the first portion in a ring manner.

3. The apparatus of claim 1, wherein the reformed layer former partially reforms the first substrate by a laser.

4. The apparatus of claim 1, wherein the peeling layer is only formed in the second portion out of the first portion and the second portion.

5. The apparatus of claim 1, wherein the peeling layer former forms the peeling layer by a laser.

6. The apparatus of claim 1, wherein the heater heats the first portion or the second portion such that a temperature of the second portion becomes higher than a temperature of the first portion.

7. The apparatus of claim 1, wherein the heater heats the first portion or the second portion such that a difference between a temperature of the first portion and a temperature of the second portion becomes 200° C. to 400° C.

8. The apparatus of claim 1, wherein the heater has a ring shape in planar view.

9. The apparatus of claim 1, wherein the remover heats the first portion or the second portion by the heater while rotating the first substrate and the second substrate.

10. The apparatus of claim 1, wherein the mover comprises a first holder configured to hold the second substrate, a second holder configured to hold the first portion, and a third holder configured to hold the second portion.

11. The apparatus of claim 10, wherein the first holder comprises a mechanism that cools the second substrate.

12. The apparatus of claim 10, wherein the second holder comprises a mechanism that cools the first portion.

13. The apparatus of claim 10, wherein the third holder comprises the heater that heats the second portion.

14. The apparatus of claim 10, wherein the third holder has a ring shape that surrounds the second holder.

15. The apparatus of claim 1, further comprising a carrying mechanism that carries the second portion peeled from the second substrate.

16. A semiconductor manufacturing apparatus comprising:
a heater configured to heat a first portion or a second portion in a first substrate provided on a surface of a second substrate, to divide the first portion and the second portion from each other; and
a mover configured to move the second substrate relative to the second portion, to remove the second portion from the surface of the second substrate while causing the first portion to remain on the surface of the second substrate.

17. The apparatus of claim 16, further comprising a reformed layer former configured to partially reform the first substrate to form a reformed layer between the first portion and the second portion in the first substrate,
wherein the heater heats the first portion or the second portion after the reformed layer is formed.

18. The apparatus of claim 16, further comprising a peeling layer former configured to form a peeling layer between the second portion and the second substrate,
wherein the heater heats the first portion or the second portion, to peel the second portion from the second substrate at the peeling layer and divide the first portion and the second portion from each other.

19. A method of manufacturing a semiconductor device, comprising:
partially reforming a first substrate to form a reformed layer between a first portion and a second portion in the first substrate;
forming a peeling layer between the second portion and a second substrate provided on a surface of the first substrate;
heating the first portion or the second portion, to peel the second portion from the second substrate at the peeling layer and divide the first portion and the second portion from each other; and
moving the second substrate relative to the second portion, to remove the second portion from a surface of the second substrate while causing the first portion to remain on the surface of the second substrate.
